(19) United States
(12) Patent Application Publication
(10) Pub. No.: US 2013/0192672 A1
(43) Pub. Date: Aug. 1, 2013

(54) PHOTOELECTRIC DEVICE

(71) Applicants: Sang-Hyuk AHN, Yongin-si (KR); Do-Young PARK, Yongin-si (KR); Nam-Choul YANG, Yongin-si (KR)

(72) Inventors: Sang-Hyuk AHN, Yongin-si (KR); Do-Young PARK, Yongin-si (KR); Nam-Choul YANG, Yongin-si (KR)

(21) Appl. No.: 13/593,797

(22) Filed: Aug. 24, 2012

(30) Foreign Application Priority Data
Jan. 31, 2012 (KR) 10-2012-0009738

(51) Int. Cl. H01L 31/0224

(52) U.S. Cl. 136/256

(57) ABSTRACT

A photoelectric device including a first substrate including at least one light absorption layer and a first grid electrode thereon, the first grid electrode withdrawing light-generated carriers of the at least one light absorption layer; a second substrate facing the first substrate, the second substrate including a second grid electrode thereon; and a protection layer covering the first and second grid electrodes, wherein the protection layer includes a first sealing member on the first grid electrode and the second grid electrode, and a second sealing member on the first sealing member, the second sealing member including a vanadium-containing glass frit and the first sealing member including a material different from that of the second sealing member.

### BACKGROUND

1. Field

Embodiments relate to a photoelectric device.

2. Description of the Related Art

As a source of energy that replaces fossil fuel, a photoelectric device (for converting light energy into electric energy) has been considered. For example, solar cells using sunlight have drawn wide attention.

Studies on solar cells having various driving principles have been performed. Among those, silicon or crystalline solar cells of a wafer type using p-n junction of a semiconductor have been considered. However, manufacturing costs of the silicon or crystalline solar cells may be high due to its process characteristic of forming and handling a high purity semiconductor material.

### SUMMARY

Embodiments are directed to a photoelectric device.

The embodiments may be realized by providing a photoelectric device including a first substrate including at least one light absorption layer and a first grid electrode thereon, the first grid electrode withdrawing light-generated carriers of the at least one light absorption layer; a second substrate facing the first substrate, the second substrate including a second grid electrode thereon; and a protection layer covering the first and second grid electrodes, wherein the protection layer includes a first sealing member on the first grid electrode and the second grid electrode, and a second sealing member on the first sealing member, the second sealing member including a vanadium-containing glass frit and the first sealing member including a material different from that of the second sealing member.

The photoelectric device may further include an electrolyte between the first and second substrates, the second sealing member contacting the electrolyte.

The first sealing member may include a bismuth-containing glass fit.

The first sealing member may include a polyimide resin.

The first and second grid electrodes may each include silver.

The vanadium-containing glass fit of the second sealing member may include vanadium oxide (V₂O₅).

The first grid electrode may include first finger electrodes, the second grid electrode may include second finger electrodes, and the second finger electrodes may be arranged at an electrode pitch that is narrower than an electrode pitch of the first finger electrodes.

The at least one light absorption layer may be arranged between neighboring first finger electrodes, and the second finger electrodes may be densely arranged under the light absorption layer.

The first substrate may include a plurality of light absorption layers thereon, one group of the second finger electrodes may be arranged under one of the light absorption layers, another group of the second finger electrodes may be arranged under another of the light absorption layers, the one group and the other group providing a plurality of groups of second finger electrodes, and an electrode pitch between the second finger electrodes of the groups of second finger electrodes may be narrower than a distance between adjacent ones of the groups of second finger electrodes.

Portions of the first and second grid electrodes may extend along edges of the first and second substrates, the portions the first and second grid electrodes at the edges of the first and second substrates overlapping one another.

The first and second sealing members may extend along the edges of the first and second substrates along with the first and second grid electrodes.

Portions of the first and second sealing members at the edges of the first and second substrates may contact each other to form a sealing layer that seals a gap between the first and second substrates.

The photoelectric device may further include a first conductive layer between the first substrate and the first grid electrode; and a second conductive layer between the second substrate and the second grid electrode.

The photoelectric device may further include a reduction catalyst layer between the second grid electrode and the second conductive layer.

### BRIEF DESCRIPTION OF THE DRAWINGS

Features will become apparent to those of ordinary skill in the art by describing in detail exemplary embodiments with reference to the attached drawings in which:

FIG. 1 illustrates an exploded perspective view of a photoelectric device according to an embodiment;

FIG. 2 illustrates a cross-sectional view taken along line of FIG. 1;

FIGS. 3A and 3B illustrate cross-sectional views comparatively showing corresponding portions between a Comparative Example and an Example Embodiment;

FIGS. 4 and 5 illustrate exploded perspective views showing a structure of a sealing layer according to an embodiment; and

FIG. 6 illustrates a cross-sectional view of a photoelectric device according to an embodiment.

### DETAILED DESCRIPTION

Korean Patent Application No. 10-2012-0009738, filed on Jan. 31, 2012, in the Korean Intellectual Property Office, and entitled: “Photoelectric Device,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

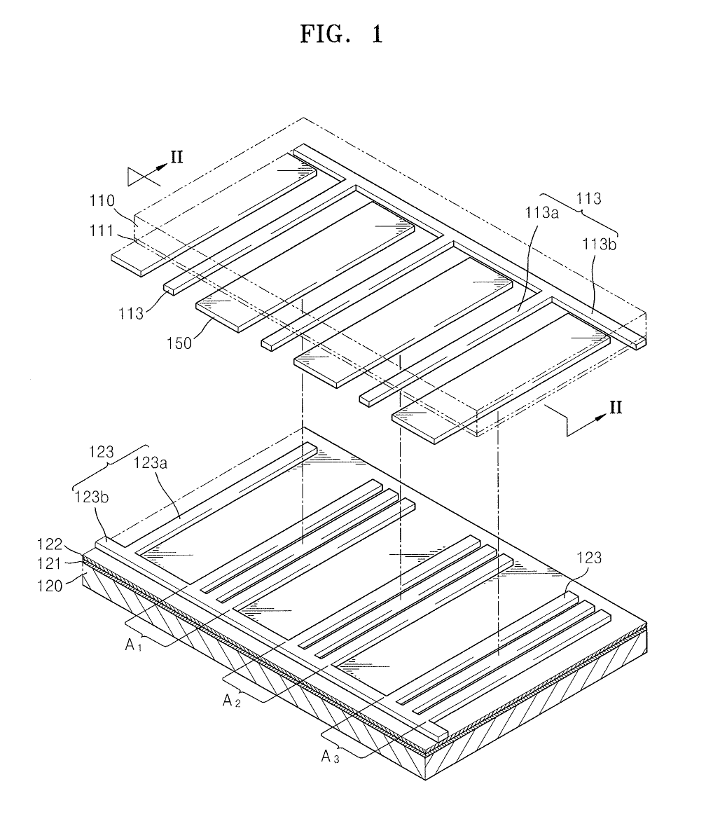

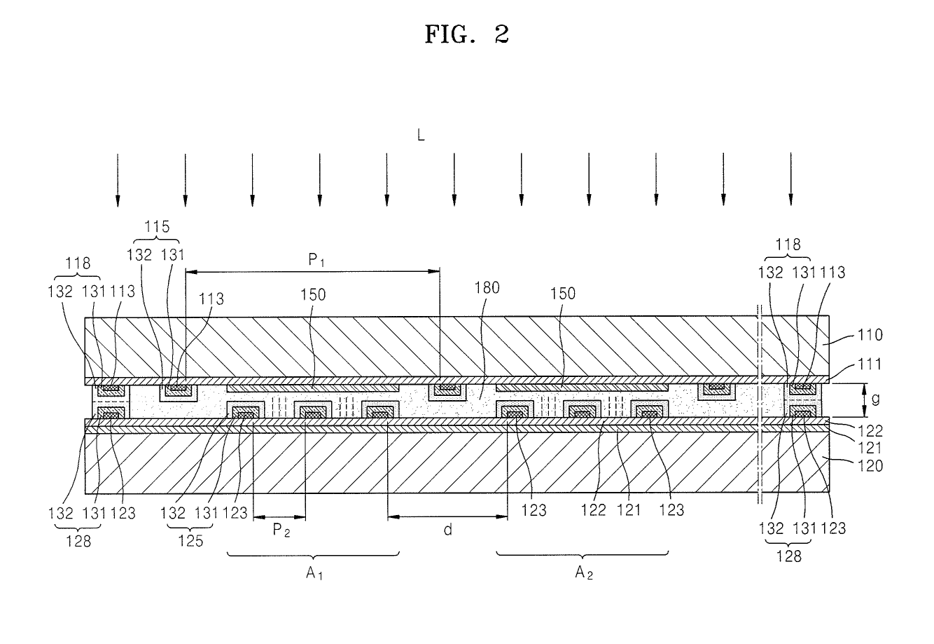

FIG. 1 illustrates an exploded perspective view of a photoelectric device according to an embodiment. FIG. 2 illustrates a cross-sectional view taken along line II-II of FIG. 1.

Referring to FIGS. 1 and 2, a first substrate 110 (including a first grid electrode 113 thereon) and a second substrate 120 (including a second grid electrode 123 thereon) may be arranged to face each other. At least one light absorption layer 150 may be formed adjacent to the first grid electrode 113 and may face the second grid electrode 123.

For example, the light absorption layer 150 may be patterned between portions of the first grid electrode 113 on the first substrate 110. A reduction catalyst layer 122 may be formed on an entire surface of the second substrate 120, e.g., between the second substrate 120 and the second grid electrode 123. However, positions of the light absorption layer 150 and the reduction catalyst layer 122 are not limited thereto.

In an implementation, the first substrate 110 may form a light receiving surface. The first grid electrode 113 (on the first substrate 110) may be a negative electrode for withdrawing light-generated carriers, e.g., electrons. The second substrate 120 may be at a rear surface, e.g., opposite to the light receiving surface. The second grid electrode 123 (on the second substrate 120) may be a positive electrode for accommodating a flow of current passing through an external circuit.

First and second conductive layers 111 and 121 may be formed on the first and second substrates 110 and 120, respectively. The first and second grid electrodes 113 and 123, together with the first and second conductive layers 111 and 121, may form a negative electrode or a positive electrode of the photoelectric device. For example, the first and second conductive layers 111 and 121 may be transparent conductive layers. In an implementation, the first and second conductive layers 111 and 121 may be formed of, e.g., a transparent conductive oxide (TCO). The first and second grid electrodes 113 and 123 (on the first and second conductive layers 111 and 121) may help reduce electric resistance of a current path by supplementing electric conductivity of the first and second conductive layers 111 and 121.

The first and second grid electrodes 113 and 123 may include a plurality of first and second finger electrodes 113a and 123a (respectively extending in parallel with one another as a pattern of strips) and first and second collector electrodes 113b and 123b (respectively extending across the first and second finger electrodes 113a and 123a and collecting the first and second finger electrodes 113a and 123a). For example, the first and second collector electrodes 113b and 123b may form electrical contact points with an external circuit or may be connected to another photoelectric device serially or parallelly, thereby forming a module structure.

Referring to FIG. 2, the first substrate 110 (including the first grid electrode 113 thereon) may function as a light receiving surface for accommodating or receiving incident light L. In order to accommodate or receive a greatest amount of the incident light L as possible, the first grid electrode 113 may have a higher aperture ratio than that of the second grid electrode 123.

The aperture ratio may refer to a relative ratio of an exposed area of the first and second grid electrodes 113 and 123, except for an area occupied by the first and second grid electrodes 113 and 123, of a total area of the first and second substrates 110 and 120. The first and second grid electrodes 113 and 123 may be formed of an opaque metal material exhibiting high electrical conductivity. Accordingly, the aperture ratio of each of the first and second substrates 110 and 120 may indicate an effective incident area for effectively accommodating or receiving the incident light L.

The first grid electrode 113 (at the light receiving surface) may have a higher aperture ratio than that of the second grid electrode 123 (at the rear surface thereof). As a large amount of the incident light L may be accommodated or received through the first grid electrode 113, loss of light may be reduced, and photoelectric efficiency may be improved. For example, a first electrode pitch P1 of the first grid electrode 113 may be greater than a second electrode pitch P2 of the second grid electrode 123.

The light absorption layer 150 may be provided between the neighboring first grid electrodes 113, e.g., neighboring first finger electrodes 113a, and may be arranged at an interval of the first electrode pitch P1 (that is greater than the second electrode pitch P2) so as to accommodate or received the greatest amount of the incident light L as possible.

As noted above, the second grid electrode 123 may be formed at the surface opposite to the light receiving surface. Thus, there may be relatively less need to consider an aperture ratio. Accordingly, by densely arranging the second grid electrode 123, e.g., the second finger electrodes 123a, at an interval of the second electrode pitch P2 (that is relatively narrow), a low resistance current path may be formed so that a decrease in efficiency due to the loss of resistance may be reduced and/or prevented.

The second grid electrode 123, e.g., the second finger electrodes 123a, may be densely arranged in an area facing the light absorption layer 150, e.g., under the light absorption layer 150, forming groups A1, A2, and A3, respectively.

For example, the second grid electrodes 123, e.g., the second finger electrodes 123a, of one group A1 may be arranged under one light absorption layer 150, and the second grid electrodes 123, e.g., the second finger electrodes 123a, of another group A2 may be arranged under another light absorption layer 150. The second grid electrodes 123, e.g., the second finger electrodes 123a, of the group A1 may be densely arranged at an interval corresponding to the second electrode pitch P2. Similarly, the second grid electrodes 123, e.g., the second finger electrodes 123a, of the group A2 may be densely arranged at an interval corresponding to the second electrode pitch P2. The group A1 of the second grid electrodes 123, e.g., the second finger electrodes 123a, and the group A2 of the second grid electrodes 123, e.g., the second finger electrodes 123a, may be separated from each other at a distance d that is greater than the second electrode pitch P2. The distance d may be an interval between the second grid electrode 123, e.g., the second finger electrodes 123a, of the group A1 and the second grid electrode 123, e.g., the second finger electrodes 123a, of the group A2 that are closest to each other and may be greater than the second electrode pitch P2.

As the light absorption layer 150 and the second grid electrode 123, e.g., the second finger electrodes 123a, may be vertically arranged to face each other, transfer of electrons between the light absorption layer 150 and the reduction catalyst layer 122 may be promoted.

For example, the reduction catalyst layer 122 may function as a reducing catalyst by receiving electrons provided via the second grid electrode 123 and reducing an electrolyte 180, and finally reduces again the light absorption layer 150 that is oxidized according to the withdrawing of the light-generated electrons. As described above, the light absorption layer 150 and an array of the second grid electrode 123, e.g., the second finger electrodes 123a, may face each other. Thus, an electric field between the light absorption layer 150 and the second grid electrode 123, e.g., the second finger electrodes 123a, may be reinforced so that the transfer of electrons to the light absorption layer 150 may be reinforced.

Ion mobility may be improved by reducing a gap between the light absorption layer 150 and the reduction catalyst layer 122 (between the second grid electrodes 123, e.g., the second finger electrodes 123a). As described above, the reduction catalyst layer 122 may receive electrons via the second grid electrode 123. Thus, portions of the reduction catalyst layer 122 adjacent to the second grid electrode 123, e.g., portions of the reduction catalyst layer 122 between the second finger electrodes 123a may contribute greatly to reduction of the light absorption layer 150. Accordingly, by forming the array of the second grid electrode 123, e.g., the second finger electrodes 123a, and the light absorption layer 150 in areas facing each other, the transfer of electrons between the light absorption layer 150 and the reduction catalyst layer 122 (between the second finger electrodes 123a) may be promoted and thus a photoelectric efficiency may be improved.

First and second protection layers 115 and 125 may be formed on surfaces of the first and second grid electrodes 113 and 123, respectively. The first and second protection layers 115 and 125 may help reduce and/or prevent corrosion of the first and second grid electrodes 113 and 123 (caused by reaction with the electrolyte 180 or intrusion of elution of the first and second grid electrodes 113 and 123 into the electrolyte 180). Thus, adverse effects on an electrochemical operation of a photoelectric device may be reduced and/or prevented.

The first and second protection layers 115 and 125 may include a first sealing member 131 (on surfaces of the first and second grid electrodes 113 and 123) and a second sealing member 132 (on the first sealing member 131). The first and second sealing members 131 and 132 may be formed of different materials and may have different functions. For example, while the second sealing member 132 may help prevent intrusion of the electrolyte 180, the first sealing member 131 may help separate the second sealing member 132 and the first and second grid electrodes 113 and 123 from each other and thus help prevent chemical reaction therebetween.

In an implementation, the first sealing member 131 may be formed of a material having lower reactivity with respect to the first and second grid electrodes 113 and 123 and exhibiting superior chemical stability with respect to the first and second grid electrodes 113 and 123. For example, the first sealing member 131 may include a glass frit of a bismuth (Bi) family, e.g., a bismuth-containing glass frit, or a material of a polyimide resin family, e.g., a polyimide resin material.

The first sealing member 131 may undergo a firing process after being coated (in a paste state) on the first and second grid electrodes 113 and 123. The first sealing member 131 may maintain chemical stability with respect to the first and second grid electrodes 113 and 123 at a firing temperature of about 300° C. to 400° C. Also, even when exposed for a long time at an operation temperature of about 85° C., the first sealing member 131 may maintain chemical stability with respect to the first and second grid electrodes 113 and 123.

If a sealing characteristic of the first sealing member 131 were to be degraded due to a reaction with the first and/or second grid electrodes 113 and 123, e.g., if the first sealing member 131 were not able to maintain formal stability to cover the first and second grid electrodes 113 and 123 with a sufficiently thickness, the electrolyte 180 could intrude into the first and second grid electrodes 113 and 123 so that the first and second grid electrodes 113 and 123 could be corroded. Also, if the electrical characteristic of the first and second grid electrodes 113 and 123 were to be changed due to a reaction with the first sealing member 131, an output characteristic of a photoelectric device could be adversely influenced.

In an implementation, a main function of the first sealing member 131 may be to separate the first and second grid electrodes 113 and 123 and the second sealing member 132 and to help prevent chemical reaction therebetween. As will be described in greater detail below, a material of the vanadium (V) family, e.g., a vanadium-containing material, exhibiting a superior chemical stability with respect to the electrolyte 180 may be used for the second sealing member 132. Vanadium-containing materials may be reactive with respect to the first and second grid electrodes 113 and 123 (formed of a metal material), especially first and second grid electrodes 113 and 123 formed of a silver (Ag) material. The first sealing member 131 (formed of, e.g., a bismuth-containing glass frit or a polyimide resin material) may help reduce and/or prevent a chemical reaction between the first and second grid electrodes 113 and 123 and the second sealing member 132. For example, the first sealing member 131 may maintain chemical stability even when contacting the first and second grid electrodes 113 and 123 formed of a silver (Ag) material.

The second sealing member 132 may be formed of a material exhibiting lower reactivity with respect to the electrolyte 180 and a superior chemical stability with respect to the electrolyte 180. In an implementation, the second sealing member 132 may include a vanadium-containing glass frit, e.g., a vanadium oxide (V₂O₅)-containing glass frit, as a material exhibiting a superior chemical stability with respect to the electrolyte 180. The second sealing member 132 may maintain chemical stability with respect to the electrolyte 180 even when exposed for a long time in an operational environment of a high temperature of about 85° C.

If the second sealing member 132 were to melt or degrade in response to a reaction with the electrolyte 180, or if the formal stability of covering the first and second grid electrodes 113 and 123 with a sufficient thickness were not able to be maintained, the electrolyte 180 could intrude into the first and second grid electrodes 113 and 123 so that the first and second grid electrodes 113 and 123 could be corroded. Also, if an ingredient of the second sealing member 132 were to be eluted into the electrolyte 180 due to a reaction with the electrolyte 180, an electrochemical operation of a photoelectric device could be affected and thus a photoelectric efficiency could be degraded.

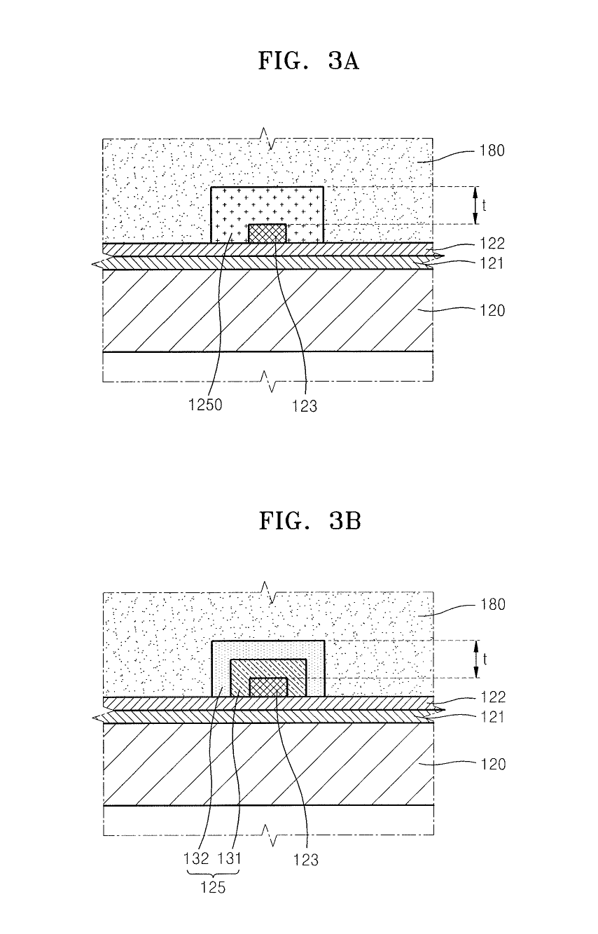

FIGS. 3A and 3B illustrate cross-sectional views comparatively showing corresponding portions between a Comparative Example and an Example Embodiment. Referring to FIG. 3A, in the Comparative Example, a single protection layer 1250 may be formed of a glass frit of the bismuth family, e.g., a bismuth-containing glass frit. The bismuth-containing glass frit may exhibit a low reactivity with respect to the grid electrode 123, but may be susceptible to intrusion of the electrolyte 180. Accordingly, the grid electrode 123 may be corroded unless a thickness t of the single protection layer 1250 is sufficiently large, e.g., about 40 μm or more.

Referring to FIG. 3B, according to an Example Embodiment, a protection layer 125 may have a dual structure (including the first and second sealing members 131 and 132 performing different functions).

The second sealing member 132 may help reduce and/or prevent intrusion of the electrolyte 180. The vanadium-containing glass frit (exhibiting superior chemical stability with respect to the electrolyte 180) may be used as the second sealing member 132. Accordingly, while reducing a thickness t of the protection layer 125, intrusion of the electrolyte 180 may be effectively prevented.

As described above, the first sealing member 131 may help prevent a reaction between the grid electrode 123 and the second sealing member 132. The first sealing member 131 may be formed of the bismuth-containing glass frit or the polyimide resin material. Thus, the reaction between the grid electrode 123 (formed of e.g., a silver (Ag) material) and the second sealing member 132 may be effectively prevented.

While the vanadium-containing glass frit (exhibiting superior chemical stability with respect to the electrolyte 180) may be used to form the second sealing member 132 (at an outside of the protection layer 125), and the first sealing member 131 formed of bismuth-containing glass frit or the polyimide resin material may be applied between the second sealing member 132 and the grid electrode 123 to separate them, the thickness t of the protection layer 125 may be reduced, and corrosion of the grid electrode 123 may be effectively prevented.

Table 1 below shows a result of testing an anti-corrosion characteristic of a grid electrode. In Table 1, the Comparative Example and the Example Embodiment had structures of FIGS. 3A and 3B, respectively.

TABLE 1

| | Comparative | | | | | |
|---|---|---|---|---|---|---|
| | Example | | Example Embodiment | | | |
| Thickness of Protection Layer (μm) | 37 | 48 | 23 | 31 | 38 | 46 |
| Number of Corroded Electrodes | 6 | 0 | 8 | 5 | 0 | 0 |

The result of the Comparative Example was obtained by performing a corrosion test on the grid electrode 123 coated with the single protection layer 1250. The single protection layer 1250 was formed of bismuth-containing glass frit.

The result of the Example Embodiment was based on a corrosion test performed on the grid electrode 123 coated with the protection layer 125 of a dual structure including the first and second sealing members 131 and 132. The first sealing member 131 was formed of bismuth-containing glass frit and the second sealing member 132 was formed of vanadium-containing glass fit.

In the Comparative Example and the Example Embodiment, a number of corrosions (e.g., a number of pin holes that were formed) according to the thickness t of each of the protection layers 1250 and 125 were counted.

As shown in Table 1, in the Comparative Example, 6 corrosions were observed when the thickness t of the protection layer 1250 was about 37 μm. In the Example Embodiment, 5 corrosions (e.g., fewer than the number observed in the Comparative Example) were observed when the thickness t of the protection layer 125 was about 31 μm (e.g., at a thickness less than that of the Comparative Example).

According to an embodiment, the first and second sealing members 131 and 132 may be formed of bismuth-containing materials and vanadium-containing materials, respectively, and may have different functions. Thus, the thickness t of each of the protection layers 115 and 125 may be reduced, and a protection characteristic of the grid electrodes 113 and 123 may be improved. By reducing the thickness t of each of the protection layers 115 and 125, a frequency or number of printing processes for forming the protection layers 115 and 125 may be reduced. Also, by reducing a cell gap g between the first and second substrates 110 and 120, an ion mobility may be improved, thereby improving photoelectric efficiency.

As may be seen above with respect to the Comparative Example, when the thickness t of the protection layer 1250 is relatively thick, the frequency or number of printing processes for forming the protection layer 1250 may increase. In order to accommodate the thicker protection layer 1250, the cell gap g between the first and second substrates 110 and 120 may be increased, thereby undesirably increasing a resistance of a current path.

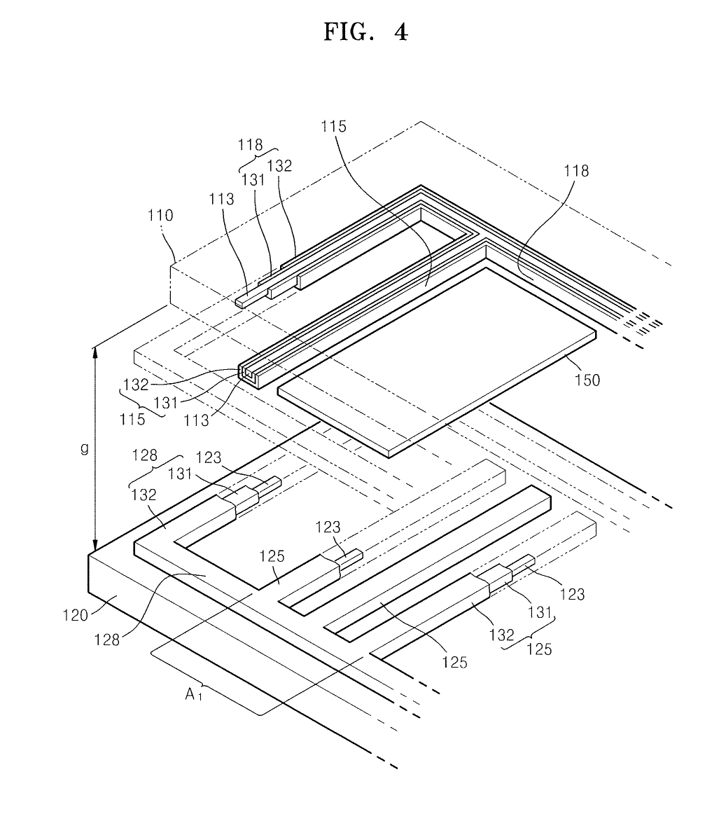

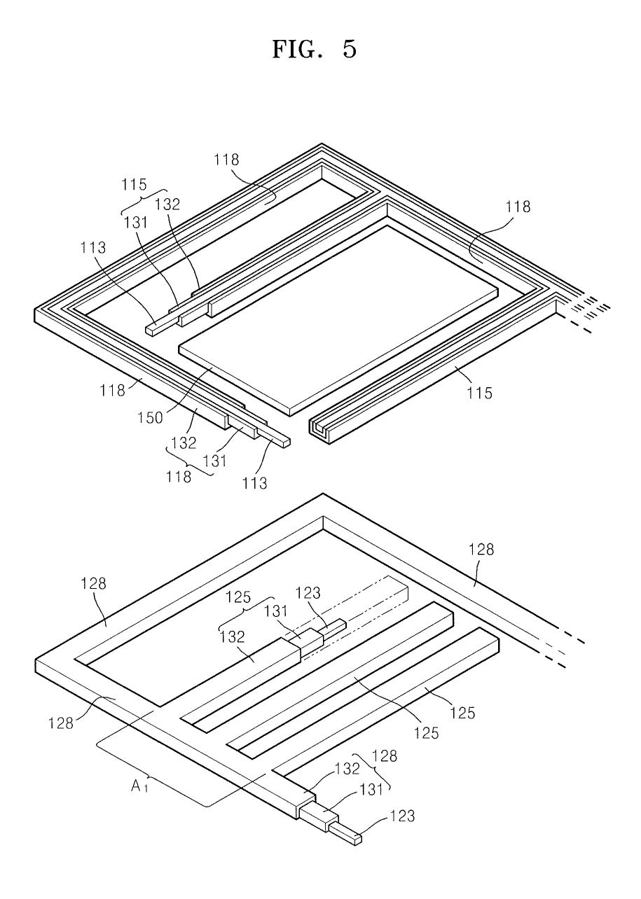

FIGS. 4 and 5 illustrate exploded perspective views showing a structure of sealing layers of a photoelectric device according to an embodiment. Referring to FIGS. 4 and 5, the photoelectric device may include the first substrate 110 (including the first grid electrode 113 thereon) and the second substrate 120 (including the second grid electrode 123 thereon). First and second sealing layers 118 and 128 may be formed between the first and second substrates 110 and 120 by combining or coupling the first and second substrates 110 and 120 to face each other.

For example, first and second sealing members 131 and 132 may be formed on surfaces of each of the first and second grid electrodes 113 and 123. The first and second sealing members 131 and 132 may form both the first and second protection layers 115 and 125 and the first and second sealing layers 118 and 128 at the same time. The first and second sealing layers 118 and 128 may seal a gap between the first and second substrates 110 and 120 and form a space for accommodating the electrolyte 180.

For example, the first and second sealing members 131 and 132 on each of the first and second grid electrodes 113 and 123 may form the first and second protection layers 115 and 125 in an inner space between the first and second substrates 110 and 120. Also, the first and second sealing members 131 and 132 on each of the first and second grid electrodes 113 and 123 may form the first and second sealing layers 118 and 128 at edges of the first and second substrates 110 and 120.

In the inner space between the first and second substrates 110 and 120, the first and second grid electrodes 113 and 123 may be formed at positions that do not overlap each other. For example, the light absorption layer 150 may be formed between neighboring portions of first grid electrode 113, e.g., neighboring first finger electrodes (see FIG. 1). Portions of the second grid electrode 123, e.g., the second finger electrodes (see FIG. 1) forming a group A1, may be densely arranged under the light absorption layer 150.

At the edges of the first and substrates 110 and 120, the first and second grid electrodes 113 and 123 may be at positions facing or overlapping with each other. For example, the first and second grid electrodes 113 and 123 may be arranged to face or overlap each other. The first and second sealing layers 118 and 128 may be formed where the first and second sealing members 131 and 132 (formed on the first and second grid electrodes 113 and 123) contact each other.

For example, the first and second sealing layers 118 and 128 (extending along the edges of the first and second substrates 110 and 120) may be formed by coupling the first and second substrates 110 and 120 where the first and second grid electrodes 113 are 123 overlap or face each other. In an implementation, the first and second sealing layers 118 and 128 may be formed where the first and second sealing members 131 and 132 (formed on the surfaces of the first and second grid electrodes 113 and 123) contact each other.

The first and second grid electrodes 113 and 123 may extend along the edges of the first and second substrates 110 and 120. For example, the first and second grid electrodes 113 and 123 may extend to surround the edges of the first and second substrates 110 and 120. The first and second sealing members 131 and 132 on the first and second grid electrodes 113 and 123 contacting each other may form the first and second sealing layers 118 and 128 extending along the edges of the first and second substrates 110 and 120. For example, the first and second sealing layers 118 and 128 may include the first sealing member 131 (formed on each of the first and second grid electrodes 113 and 123) and the second sealing member (formed on the first sealing member 131).

According to an embodiment, a cell gap g between the first and second substrates 110 and 120 may be reduced by forming the first and second sealing layers 118 and 128 using the first and second sealing members 131 and 132 (formed on the first and second grid electrodes 113 and 123) without providing a separate sealing member between the first and second substrates 110 and 120. Thus, ion mobility of the electrolyte 180 (mediating the electrical connection between the first and second grid electrodes 113 and 123) may be improved. Also, resistance of a current path may be reduced. Thus, photoelectric efficiency may be improved.

As described above, the first and second protection layers 115 and 125 may be formed by using the first and second sealing members 131 and 132 having different functions. Thus, the thickness t of each of the first and second protection layers 115 and 125 may be reduced. Accordingly, the cell gap g between the first and second substrates 110 and 120 for accommodating the first and second protection layers 115 and 125 may be further reduced.

Table 2 shows a result of comparison of a photoelectric efficiency between a Comparative Example and an Example Embodiment.

| | Comparative Example | | | Example Embodiment | | |
|---|---|---|---|---|---|---|
| | Serial No. | | | | | |
| | #1 | #2 | #3 | #4 | #5 | #6 |
| Photoelectric | 100 | 103.1 | 83.2 | 117.8 | 115.9 | 116.4 |
| Efficiency | | | | | | |

According to the Comparative Example, photoelectric efficiency was measured on a structure having the single protection layer 1250 formed of a bismuth-containing glass frit and a separate sealing member (not shown) provided between the first and second substrates 110 and 120, as illustrated in FIG. 3A.

According to the Example Embodiment, photoelectric efficiency was measured on a structure having the grid electrode 123 coated with the first and second protection layers 115 and 125 of a dual structure including the first sealing member 131 formed of a bismuth-containing glass frit and the second sealing member 132 formed of a vanadium-containing glass frit, and the first and second sealing layers 118 and 128 using the first and second sealing members 131 and 132, as illustrated in FIGS. 4 and 5. The cell gap g of the Example Embodiment was reduced to ⅓ the size of the cell gap of the Comparative Example.

The values of the Comparative Example and the Example Embodiment were relative photoelectric efficiencies obtained through three measurements based on a standard of 100 points.

As may be seen in Table 2, the average of photoelectric efficiencies in the

Comparative Example was 95.4 and the average of photoelectric efficiencies in the Example Embodiment was 116.7. As a result, it may be seen that the photoelectric efficiency of the Example Embodiment was improved by about 20% compared to that of the Comparative Example.

Each constituent element of the photoelectric device is described in detail with reference to FIG. 2. The first and second substrates 110 and 120 may be formed of a transparent material or a material having a high light transmissivity. For example, the first and second substrates 110 and 120 may be formed of a glass material as a glass substrate, or a resin film. The resin film may be flexible, if flexibility is desired.

The first and second conductive layers 111 and 121 on the first and second substrates 110 and 120, respectively, may have electrical conductivity and may be formed of a transparent conductive material having optical transparency, e.g., a transparent conductive oxide (TCO) such as an indium tin oxide (ITO), a fluorine-doped tin oxide (FTO), an antimony tin oxide (ATO), or the like.

The first and second grid electrodes 113 and 123 formed on the first and second substrates 110 and 120, respectively, may be formed of an opaque metal material exhibiting a high electrical conductivity, e.g., aluminum (Al), silver (Ag), or the like.

The light absorption layer 150 between the first grid electrodes 113, e.g., between the first finger electrodes 113a (see FIG. 1) may include a semiconductor layer and a photosensitive dye adsorbed on the semiconductor layer. For example, the semiconductor layer may be formed of an oxide of a metal such as Cd, Zn, In, Pb, Mo, W, Sb, Ti, Ag, Mn, Sn, Zr, Sr, Ga, Si, Cr, or the like.

In an implementation, the photosensitive dye adsorbed on the semiconductor layer may include a molecule capable of absorbing light in a visible range and facilitating rapid movement of electrons from the semiconductor layer in an optically excited state. For example, a photosensitive dye of a ruthenium (Ru) family may be used as the photosensitive dye.

The reduction catalyst layer 122 between the second grid electrode 123 and the second conductive layer 121 may be formed of a material having a reducing catalyst function to supply electrons to the electrolyte 180, e.g., metal such as platinum (Pt), gold (Au), silver (Ag), copper (Cu), aluminum (Al), or the like, a metal oxide such as tin oxide (SnO₂), or a material of a carbon (C) family such as graphite. A redox electrolyte including a pair of an oxidizing agent and a reducing agent may be used as the electrolyte 180 between the light absorption layer 150 and the reduction catalyst layer 122.

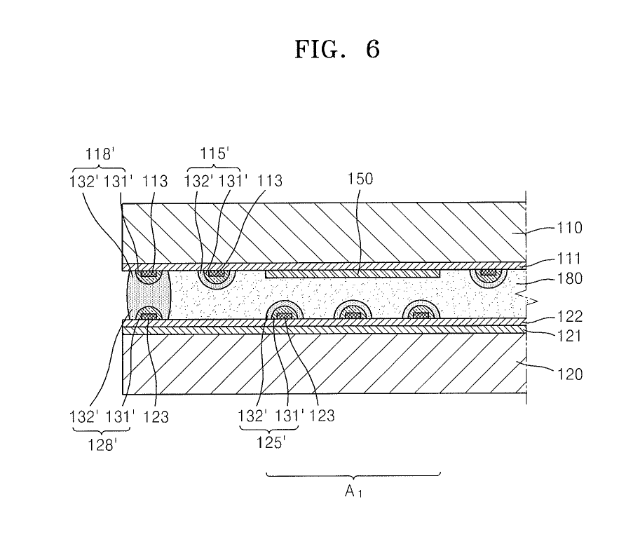

In FIG. 2, surfaces of the protection layers 115 and 125 and the sealing layers 118 and 128 are illustrated as being angled along the first and second grid electrodes 113 and 123. However, the embodiments are not limited thereto. p FIG. 6 illustrates a cross-sectional view of a photoelectric device according to an embodiment. Referring to FIG. 6, surfaces of first and second protection layers 115′ and 125′ and first and second sealing layers 118′ and 128′ may be formed as gradually rounded surfaces covering the first and second grid electrodes 113 and 123. For example, first and second sealing members 131′ and 132′ (forming the protection layers 115′ and 125′ and the first and second sealing layers 118′ and 128′) may be formed as rounded surfaces on the first and second grid electrodes 113 and 123.

According to an embodiment, the protection layer coating the grid electrode may have a dual structure of the first and second sealing members having different material characteristics. Thus, the thickness of the protection layer may be reduced. Accordingly, the frequency or number of the printing processes for forming the protection layer may be reduced, and the cell gap between the first and second substrates may be reduced.

Furthermore, the sealing layer may be formed using the first and second sealing members formed on the grid electrode without using a separate sealing structure. Thus, the cell gap between the first and second substrates may be further reduced.

By way of summation and review, unlike the silicon solar cell, a dye-sensitized solar cell may include a photosensitive dye (capable of generating excited electrons or excitons by receiving incident light having a wavelength in a visible region), a semiconductor material (capable of accepting the excited electrons), and an electrolyte (reacting on or with electrons returning after working at an external circuit). The dye-sensitized solar cell may be desirable as a next generation solar cell due to its remarkably high photoelectric conversion efficiency compared to a conventional solar cell.

In the dye-sensitized solar cell, a grid electrode may withdraw light-generated electrons at a light receiving surface, and a protection layer may be formed on a surface of the grid electrode to protect the grid electrode from a, e.g., strongly corrosive, electrolyte. To help prevent corrosion of the grid electrode, the protection layer may have a considerable thickness. Accordingly, a cell gap may increase, and photoelectric efficiency may be degraded.

The embodiments provide a photoelectric device that may help sufficiently protect a grid electrode while thinning a protection layer of the grid electrode.

The embodiments provide a photoelectric device that may help reduce a cell gap by improving a sealing structure while thinning a protection layer of a grid electrode.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photoelectric device, comprising:
a first substrate including at least one light absorption layer and a first grid electrode thereon, the first grid electrode withdrawing light-generated carriers of the at least one light absorption layer;
a second substrate facing the first substrate, the second substrate including a second grid electrode thereon; and
a protection layer covering the first and second grid electrodes,
wherein the protection layer includes:
a first sealing member on the first grid electrode and the second grid electrode, and
a second sealing member on the first sealing member, the second sealing member including a vanadium-containing glass fit and the first sealing member including a material different from that of the second sealing member.

2. The photoelectric device as claimed in claim 1, further comprising an electrolyte between the first and second substrates, the second sealing member contacting the electrolyte.

3. The photoelectric device as claimed in claim 1, wherein the first sealing member includes a bismuth-containing glass frit.

4. The photoelectric device as claimed in claim 1, wherein the first sealing member includes a polyimide resin.

5. The photoelectric device as claimed in claim 1, wherein the first and second grid electrodes each include silver.

6. The photoelectric device as claimed in claim 1, wherein the vanadium-containing glass frit of the second sealing member includes vanadium oxide (V₂O₅).

7. The photoelectric device as claimed in claim 1, wherein:
the first grid electrode includes first finger electrodes,
the second grid electrode includes second finger electrodes, and
the second finger electrodes are arranged at an electrode pitch that is narrower than an electrode pitch of the first finger electrodes.

8. The photoelectric device as claimed in claim 7, wherein:
the at least one light absorption layer is arranged between neighboring first finger electrodes, and
the second finger electrodes are densely arranged under the light absorption layer.

9. The photoelectric device as claimed in claim 8, wherein:
the first substrate includes a plurality of light absorption layers thereon,
one group of the second finger electrodes is arranged under one of the light absorption layers,
another group of the second finger electrodes is arranged under another of the light absorption layers, the one group and the other group providing a plurality of groups of second finger electrodes, and
an electrode pitch between the second finger electrodes of the groups of second finger electrodes is narrower than a distance between adjacent ones of the groups of second finger electrodes.

10. The photoelectric device as claimed in claim 1, wherein portions of the first and second grid electrodes extend along edges of the first and second substrates, the portions the first and second grid electrodes at the edges of the first and second substrates overlapping one another.

11. The photoelectric device as claimed in claim 10, wherein the first and second sealing members extend along the edges of the first and second substrates along with the first and second grid electrodes.

12. The photoelectric device as claimed in claim 11, wherein portions of the first and second sealing members at the edges of the first and second substrates contact each other to form a sealing layer that seals a gap between the first and second substrates.

13. The photoelectric device as claimed in claim 1, further comprising:
a first conductive layer between the first substrate and the first grid electrode; and
a second conductive layer between the second substrate and the second grid electrode.

14. The photoelectric device as claimed in claim 13, further comprising a reduction catalyst layer between the second grid electrode and the second conductive layer.
